(19) United States
(12) Patent Application Publication
(10) Pub. No.: US 2006/0087347 A1
(43) Pub. Date: Apr. 27, 2006

(54) Input circuit and semiconductor device

(75) Inventor: Yoshikazu Sumi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/253,625

(22) Filed: Oct. 20, 2005

(30) Foreign Application Priority Data
Oct. 21, 2004 (JP) 2004-306475

(51) Int. Cl. H03K 5/22

(52) U.S. Cl. 327/72

(57) ABSTRACT

An input circuit according to an embodiment of the present invention includes: a comparator circuit comparing a reference voltage with an input voltage; a resistor element provided between a power supply line supplying a power supply voltage of the comparator circuit and an input line applied with the input voltage; and a transmitting circuit transmitting a potential change of the power supply line to a reference voltage supply line supplying the reference voltage.

### BACKGROUND OF THE INVENTION

1. Field of the Invention

The present invention relates to an input circuit and a semiconductor device, in particular, an input circuit and semiconductor device for comparing an input signal voltage with a reference voltage.

2. Description of Related Art

In some conventional input circuits for comparing an input signal voltage with a reference voltage to determine its output according to the voltage difference, resistor elements are provided between an input signal line and a power supply line, and between the input signal line and a ground line. For example, Japanese Unexamined Patent Publication No. 6-204869 discloses an input circuit the input terminal of which is terminated based on the Thevenin termination so as to prevent transmission waveform from losing its regularity due to the reflection wave on the receiving side, thereby matching with characteristic impedance of a transmission line. Besides, Japanese Unexamined Patent Publication No. 11-68855 discloses an input circuit in which resistors are provided between an input signal line and a power supply line and between the input signal line and a ground line in order to accelerate the signal transmission to bias the input voltage at the time of transmitting no signal, up to the high level of the transmission signal.

FIG. 7A is a circuit diagram showing a conventional input circuit 100. An input signal voltage Vin is applied to a comparator circuit 15 through an input line 14 connected with an input pad 18, and compared with a reference voltage Vref there to put out a voltage Vout in accordance with the comparison result. The comparator circuit 15 is provided between a power supply line 11 supplying a power supply voltage VDD and a ground line 12 supplying a ground voltage GND. Reference numeral 13 denotes a reference voltage supply line supplying the reference voltage Vref, and 16 and 17 denote resistor elements.

FIG. 7B shows an example of a conventional comparator circuit. Reference symbols P1 and P2 denote P-channel transistors, and N1 and N2 denote N-channel transistors. The application of the reference voltage Vref to the gate allows current to flow through the N-channel transistor N1 up to a P-channel transistor P2 due to the configuration of a current mirror circuit composed of the P-channel transistors P1 and P2. For example, on the assumption that the P-channel transistors P1 and P2 have the same size, and the N-channel transistors N1 and N2 have the same size, if the input signal voltage Vin is lower than the reference voltage Vref, the output signal voltage Vout is at a high level, and if the input signal voltage Vin is higher than the reference voltage Vref, the output signal voltage Vout is at a low level.

FIG. 8 is a schematic plan view of an integrated circuit (semiconductor device) 101 including the plural input circuits 100 of FIG. 7A. In FIG. 8, reference numeral 18 denotes an input pad, and 41 denotes a reference voltage generator circuit for generating the reference voltage Vref. The reference voltage Vref is supplied through the reference voltage supply line 13 to the input circuit 100.

As shown in FIG. 8, if the reference voltage generator circuit 41 is remote from the input circuit 100, for example, high-frequency noise is locally superimposed on the ground line 12 around an input circuit 100a due to any factor (parasitic capacitance or through-current etc.) to change the potential of the ground voltage GND. In such a case, as understood from FIG. 7A, the input signal voltage Vin applied to the comparator circuit 15 changes but the reference voltage Vref shows almost no change.

This is because a large parasitic capacitance is additionally formed on the power supply line 11 or the ground line 12 between the reference voltage generator circuit 41 and the input circuit 100a, so the high-frequency noise is absorbed on the way from the input circuit 100a to the reference voltage generator circuit 41, and even if the high-frequency noise is superimposed on the reference voltage Vref in the reference voltage generator circuit 41, the noise components are smoothed out on the way from the reference voltage generator circuit 41 to the input circuit 100a due to its resistance components and parasitic capacitance components, on account of the long reference voltage supply line 13.

As the conventional semiconductor device having the reference voltage generator circuit, a device disclosed in Japanese Unexamined Patent Publication No. 5-121650 has been known.

The conventional input circuit of FIG. 7A has a fear that when the high-frequency noise is superimposed on the power supply line 11 or ground line 12, an erroneous operation occurs.

FIG. 9A is a timing chart of when the noise is superimposed in an upward pulse form on the ground line 12 with the input signal voltage Vin lower than the reference voltage Vref. When the ground voltage GND rises (close to the power supply voltage VDD), the input signal voltage Vin also rises because this change is brought thereto from the ground line 12 by way of the resistor element 17, and temporarily exceeds the reference voltage Vref. In response to this, the output signal voltage Vout from the comparator circuit 15 temporarily and significantly drops from the potential of the power supply voltage VDD (close to the ground voltage GND). Therefore, the erroneous operation may occur depending on the circuit configuration of the next and subsequent stages (not shown).

Similarly, FIG. 9B is a timing chart of when the noise is superimposed in a downward pulse form on the power supply line 11 with the input signal voltage Vin larger than reference voltage Vref. When the power supply voltage VDD drops, the input signal voltage Vin also drops because this change is brought thereto from the power supply line 11 by way of the resistor element 16, and temporarily falls below the reference voltage Vref. In response to this change, the output signal voltage Vout of the comparator circuit 15 temporarily and significantly increases from the potential of the ground voltage GND, leading to the erroneous operation.

In order to avoid such situations, when the high-frequency noise is superimposed on the power supply line 11 or the ground line 12, the reference voltage Vref is changed like the input signal voltage Vin.

Japanese Unexamined Patent Publication No. 11-68855 describes the input circuit incorporating the reference voltage generator circuit. With such configuration, the reference voltage Vref can be changed like the input signal voltage Vin. However, if a number of input circuits are provided, the power consumption considerably increases disadvantageously.

Japanese Unexamined Patent Publication No. 5-121650 discloses a technique of arranging reference voltage generator circuits in several predetermined regions (for example, four corners of an integrated circuit chip). However, according as the integrated circuit chip is enlarged and the number of input circuits is increased, it is more difficult to arrange all the input circuits near the reference voltage generator circuit.

### SUMMARY OF THE INVENTION

An input circuit according to the present invention includes a comparator circuit comparing a reference voltage with an input voltage. A resistor element is provided between a power supply line supplying a power supply voltage of the comparator circuit and an input line applied with the input voltage. A transmitting circuit transmits a voltage change of the power supply line to a reference voltage supply line supplying the reference voltage. According to the input circuit of the present invention, even if the high-frequency noise is superimposed on the power supply line (VDD power supply line or GND power supply line), the reference voltage changes like the input signal voltage. Consequently, the comparator circuit does not make erroneous decision to prevent an erroneous operation. In addition, there is no need to provide many reference voltage generator circuits, making it possible to save the power consumption.

Another input circuit according to the present invention includes a comparator circuit comparing a reference voltage supplied from a reference voltage supply line and an input voltage supplied from an input line. A first resistor element is provided between a first power supply line supplying a first voltage and the input line. Further, a second resistor element is provided between a second power supply line supplying a second voltage and the input line. A first high-pass filter is provided between the reference voltage supply line and the first power supply line, and a second high-pass filter is provided between the reference voltage supply line and the second power supply line. According to the input circuit of the present invention, even if the high-frequency noise is superimposed on the first power supply line or second power supply line, the reference voltage changes like the input signal voltage. Consequently, the comparator circuit does not make erroneous decision to prevent an erroneous operation. In addition, there is no need to provide many reference voltage generator circuits, and the high-pass filter is provided between the first and second power supply lines and the reference voltage supply line, making it possible to save the power consumption.

A semiconductor device according to the present invention includes an input circuit. The input circuit comprises a comparator circuit comparing a reference voltage with an input voltage. The input circuit further includes a resistor element and a transmitting circuit. The resistor element is provided between a power supply line supplying a power supply voltage of the comparator circuit and an input line applied with the input voltage. The transmitting circuit transmits a voltage change of the power supply line to a reference voltage supply line supplying the reference voltage. According to the semiconductor device of the present invention, even if the high-frequency noise is superimposed on the power supply line (VDD power supply line or GND power supply line), the reference voltage changes like the input signal voltage. Consequently, the comparator circuit never makes erroneous judgment to prevent an erroneous operation. In addition, there is no need to provide many reference voltage generator circuits, making it possible to save the power consumption.

According to the present invention, it is possible to provide an input circuit and semiconductor device capable of preventing an erroneous operation and saving the power consumption.

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram showing the configuration of an input circuit according to the present invention;

FIG. 2 is a circuit diagram showing the configuration of an input circuit according to the present invention;

FIGS. 3A and 3B are timing charts showing operational timings of an input circuit according to the present invention;

FIGS. 4A and 4B are plan views showing the structure of a capacitor element used in an input circuit according to the present invention;

FIGS. 5A and 5B are plan views showing the structure of a capacitor element used in an input circuit according to the present invention;

FIG. 6 is a circuit diagram showing the configuration of an input circuit according to the present invention;

FIGS. 7A and 7B are circuit diagrams showing the configuration of a conventional input circuit;

FIG. 8 is a plan view showing the structure of a semiconductor device having a conventional input circuit; and

FIGS. 9A and 9B are timing charts illustrative of operational timings of a conventional input circuit.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment of the Invention

First, an input circuit according to a first embodiment of the present invention is described. The input circuit according to this embodiment has a high-pass filter enabling a reference voltage Vref to follow the change in power supply voltage VDD or ground voltage GND.

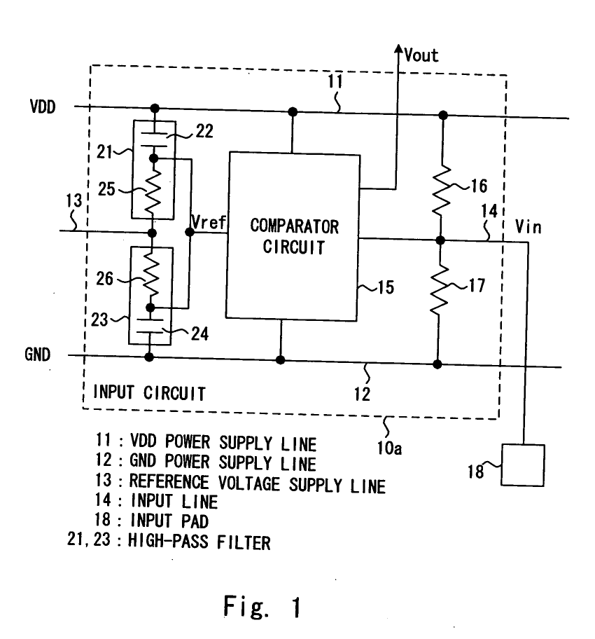

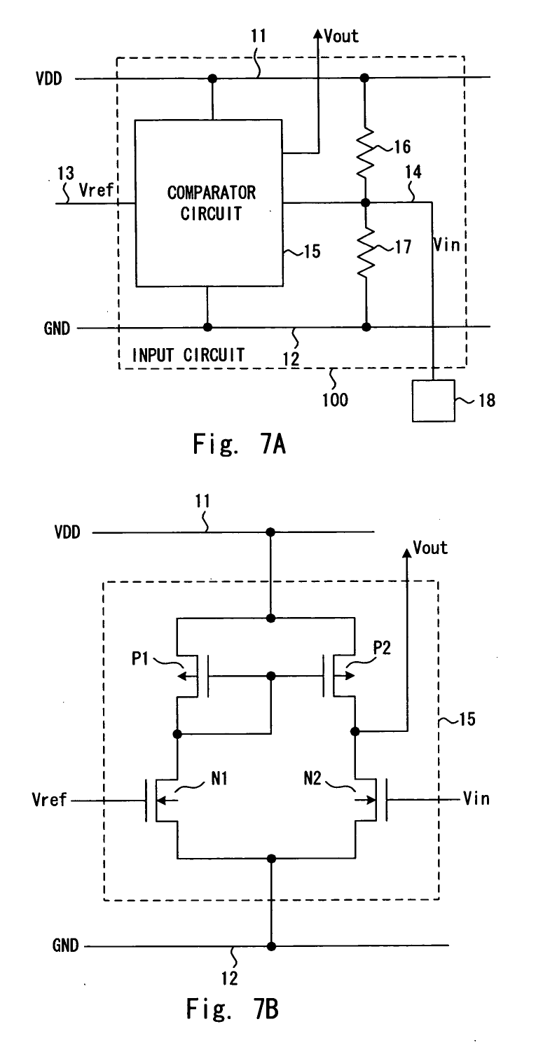

FIG. 1 is a circuit diagram showing the input circuit according to this embodiment. In FIG. 1, the same components as those of FIGS. 7A and 7B are denoted by like reference numerals, and their description is omitted if not required.

An input circuit 10a differs from a conventional input circuit 100 of FIG. 7A in that a transmitting circuit (high-pass filter) 21 is provided between the power supply line 11 and the reference voltage supply line 13 for transmitting a voltage change due to high-frequency components on the power supply line 11 to the reference voltage supply line 13, and a transmitting circuit (high-pass filter) 23 is provided between the ground line 12 and the reference voltage supply line 13 for transmitting a voltage change due to high-frequency components in the ground line 12 to the reference voltage supply line 13. Resistor elements 16 and 17 are provided between the input signal voltage Vin (input line 14) and the power supply line 11 and between the input signal voltage Vin and the ground line 12, respectively. The high-pass filters 21 and 23 are transmitting circuits for transmitting the voltage change of the power supply line 11 and the ground line 12 to the reference voltage supply line 13.

The high-pass filters 21 and 23 mainly allow transmission of signals having a frequency component of, for example, 100 MHz or more. Owing to the provision of the high-pass filter 21, when the high-frequency noise is superimposed on the power supply line 11, the reference voltage Vref is changed similar to the input signal voltage Vin. Further, owing to the provision of the high-pass filter 23, even when the high-frequency noise is superimposed on the ground line 12, the reference voltage Vref is changed like the input signal voltage Vin, making it possible to prevent the erroneous operation.

The high-pass filter 21 preferably consists of a capacitor element 22 one end of which is connected with the power supply line 11, and a resistor element 25 connected with the other end of the capacitor element 22 at one end and with the reference voltage supply line 13 at the other end. The high-pass filter 23 preferably consists of a capacitor element 24 one end of which is connected with the ground line 12, and a resistor element 26 connected with the other end of the capacitor element 24 at one end, and with the reference voltage supply line 13 at the other end. A node between the capacitor element 22 and the resistor element 25 is connected with the reference voltage Vref input terminal of the input circuit 10a. Similarly, a node between the capacitor element 24 and the resistor element 26 is also connected with the reference voltage Vref input terminal of the input circuit 10a. That is, the reference voltage Vref is applied to the comparator circuit 15 from the node between the capacitor element 22 and the resistor element 25, and the node between the capacitor element 24 and the resistor element 26.

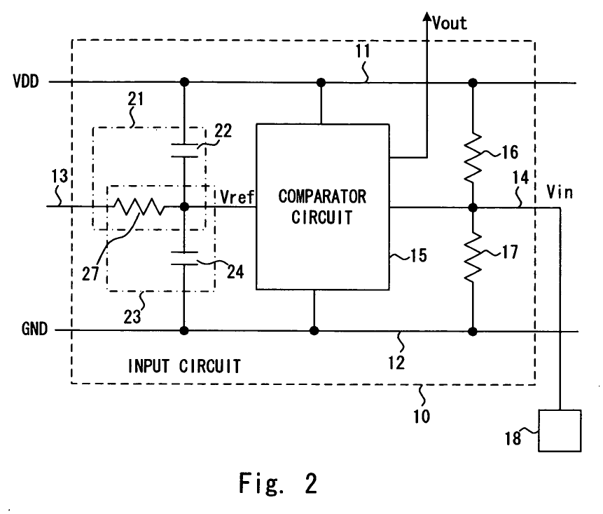

Here, as shown in FIG. 2, the resistor element 25 of the high-pass filter 21 and the resistor element 26 of the high-pass filter 23 may be integrated into a resistor element 27. In this case, the node connected in common with the capacitor element 22, the capacitor element 24, and the resistor element 27 is connected with the reference voltage Vref input terminal of the input circuit 10a, and the reference voltage Vref is supplied to the comparator circuit 15 through this node.

More preferably, a capacitance ratio between the capacitor element 22 and the capacitor element 24 is made substantially equal to a resistance radio between the resistor element 16 and the resistor element 17. In practical use, the former may be set within a range of about 80% to 120% of the latter.

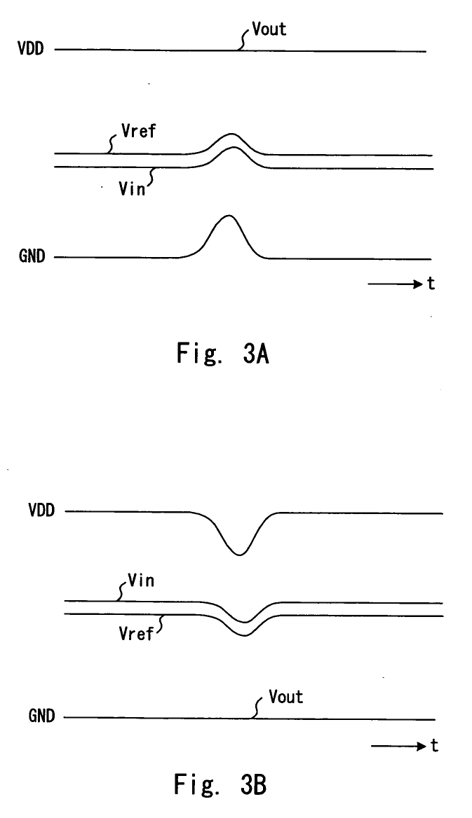

FIGS. 3A and 3B are timing charts showing beneficial effects of this embodiment. In FIGS. 3A and 3B, ratios between the resistance value of the resistor element 16 and that of the resistor element 17 and between the capacitance value of the capacitor element 22 and that of the capacitor element 24 are set as 1.

The resistor elements 25, 26, or the resistor element 27 may be formed of metal having a relatively high specific resistance such as tungsten (W) or polysilicon with the metal silicide surface. Alternatively, metal wire of low specific resistance such as aluminum (Al) alloy or copper (Cu) can be directly used as a resistor element as long as the wire secures the length long enough to achieve a requisite resistance value.

FIG. 3A corresponds to the conventional example of FIG. 9A, that is, an example in which the positive pulse noise (upward pulse) is superimposed on the ground line 12 with the input signal voltage Vin lower than the reference voltage Vref. If the ground voltage GND rises (close to the power supply voltage VDD), the input signal voltage Vin also rises because this change is brought thereto from the ground line 12 by way of the resistor element 17. Then, in this embodiment, the reference voltage Vref increases to almost the same extent because this change is brought thereto from the ground line 12 by way of the capacitor element 24, so the input signal voltage Vin never exceeds the reference voltage Vref. Therefore, the comparator circuit 15 by no means makes erroneous decision, and the output signal voltage Vout is kept at the voltage of the power supply voltage VDD, thereby preventing the erroneous operation.

Similarly, FIG. 3B corresponds to the conventional example of FIG. 9B, that is, an example in which negative (downward) pulse noise is superimposed on the power supply line 11 with the input signal voltage Vin higher than the reference voltage Vref. When the power supply voltage VDD drops (close to the ground voltage GND), the input signal voltage Vin also drops because this change is brought thereto from the power supply line 11 by way of the resistor element 16. However, the reference voltage Vref decreases to almost the same extent because this change is also brought thereto from the power supply line 11 by way of the capacitor element 22. Hence, the input signal voltage Vin never falls below the reference voltage Vref. Thus, the comparator circuit 15 by no means makes erroneous decision, and the output signal voltage Vout is kept at the potential of the ground voltage GND, thereby preventing the erroneous operation.

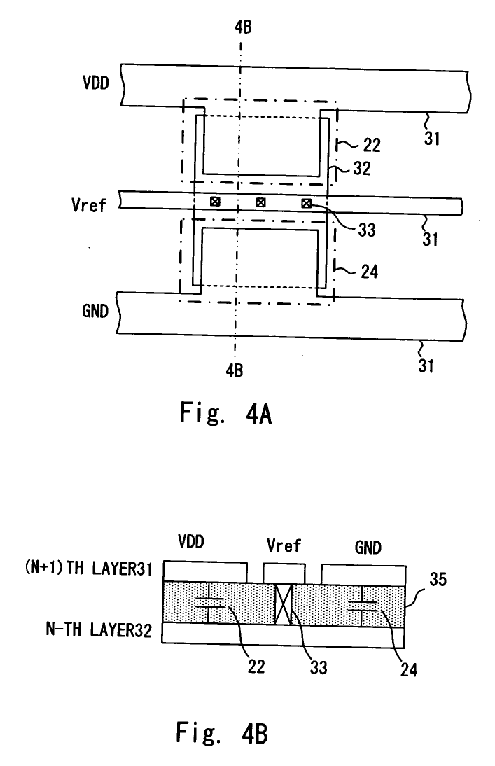

FIG. 4A is a plan view showing a structural example of the capacitor elements 22 and 24, and FIG. 4B is a sectional view taken along the line A-A′ of FIG. 4A. In FIGS. 4A and 4B, the capacitor element 22 forms a capacitor between an electrode of the (N+1)th wiring layer 31 (upper layer) applied with the power supply voltage VDD and the N-th wiring layer 32 (lower layer) formed immediately below the upper layer through an insulating film 35 face to face as viewed in section. The N-th wiring layer 32 is applied with the reference voltage Vref via the (N+1)th wiring layer 31 through via holes 33. The capacitor element 24 has similar structure.

To elaborate, FIGS. 4A and 4B show an example of forming a capacitor element using two opposite wiring layers. As shown in FIGS. 4A and 4B, in the (N+1)th wiring layer 31, an electrode (reference voltage supply line 13) supplying the reference voltage Vref, an electrode (power supply line 11) supplying the power supply voltage VDD, and an electrode (ground line 12) supplying the ground voltage GND extend in a first direction (horizontal direction of FIG. 4A). The electrode supplying the power supply voltage VDD and the electrode supplying the ground voltage GND have projections protruding towards the electrode supplying the reference voltage Vref in a second direction orthogonal to the first direction (vertical direction of FIG. 4A). The capacitor elements 22 and 24 are formed between the projections of the electrodes in the (N+1)th wiring layer 31 and the electrode of the N-th wiring layer 32 opposite thereto through the insulating film 35 formed therebetween. For example, the capacitance values of the capacitor elements 22 and 24 can be adjusted to desired ones by changing, for example, a surface area of the projections of the electrodes in the (N+1)th wiring layer.

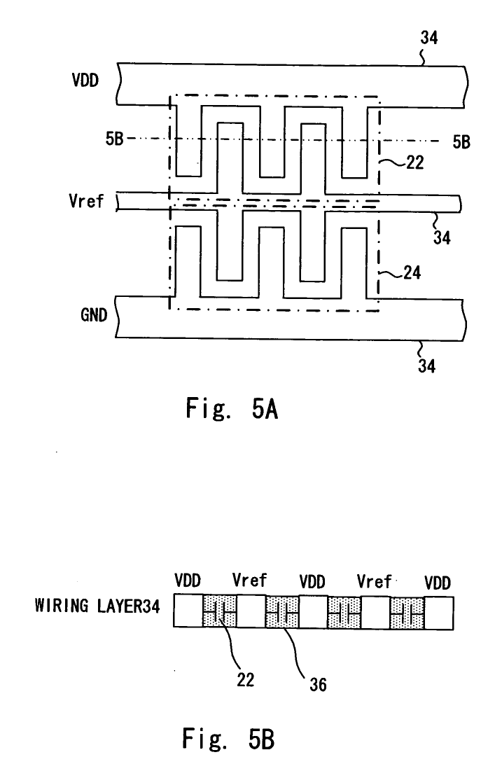

FIG. 5A is a plan view showing another structural example of the capacitor elements 22 and 24, and FIG. 5B is a sectional view taken along the line B-B′ of FIG. 5A. In FIGS. 5A and 5B, the capacitor element 22 uses an electrode of the wiring layer 34 supplied with the power supply voltage VDD as one electrode thereof, and uses, as the other electrode thereof, another electrode of the wiring layer 34 formed opposite to the one electrode in a horizontal direction as viewed in section and supplied with the reference voltage Vref. A capacitor is formed between the wall surface of the electrode of the wiring layer 34 supplied with the power supply voltage VDD and the electrode of the wiring layer 34 supplied with the reference voltage Vref through an insulating film 36. The capacitor element 24 has similar structure.

That is, FIGS. 5A and 5B show an example of forming a capacitor element using one wiring layer. As shown in FIGS. 5A and 5B, in the wiring layer 34, the electrode (reference voltage supply line 13) supplying the reference voltage Vref, the electrode (power supply line 11) supplying the power supply voltage VDD, and the electrode (ground line 12) supplying the ground voltage GND extend in the first direction (horizontal direction of FIG. 5A). The electrode supplying the power supply voltage VDD and the electrode supplying the ground voltage GND have plural projections protruding towards the electrode supplying the reference voltage Vref in the second direction (vertical direction of FIG. 5A) orthogonal to the first direction. Moreover, the electrode supplying the reference voltage Vref has plural projections on both sides, which protrude in the second direction towards both the electrode supplying the reference voltage Vref and the electrode supplying the ground voltage GND. The projections of the electrode supplying the power supply voltage VDD and the electrode supplying the ground voltage GND are formed in mesh with the projections of the electrode supplying the reference voltage Vref at given intervals through the insulating film 36. Then, the capacitor elements 22 and 24 are formed from the side faces (in section) of the projections of the electrode supplying the power supply voltage VDD and the electrode supplying the ground voltage GND, and the side faces (in section) of the projections of the electrode supplying the reference voltage Vref insulated with the insulating film 36 therebetween. For example, an interval between adjacent projections of different electrodes in the wiring layer 34, the sectional area of the adjacent electrodes, etc. are changed to adjust the capacitance values of the capacitor elements 22 and 24 to desired ones.

As mentioned above, in the input circuit of this embodiment, the high-pass filters are provided between both the power supply line and the reference voltage supply line and between the ground line and the reference voltage supply line, whereby when the high-frequency noise is superimposed on the power supply line, the reference voltage changes like the input signal voltage, and even when the high-frequency noise is superimposed on the ground line, the reference voltage also changes like the input signal voltage. Hence, the reference voltage can follow the input signal, the comparator circuit 15 never makes erroneous judgment to prevent the erroneous operation. Further, there is no need to provide many reference voltage generator circuits, and the formation of the capacitor elements between both the power supply line and the ground line, and the reference voltage supply line suppresses the power consumption. Furthermore, if the metal wire is directly used for the resistor element 27 of FIG. 2, an additional resistor element is not required, so the power consumption can be further reduced. Besides, the capacitor elements 22 and 24 are designed as a coupling capacitor like the layout of FIGS. 4A to 5B, whereby the capacitor element can be efficiently formed.

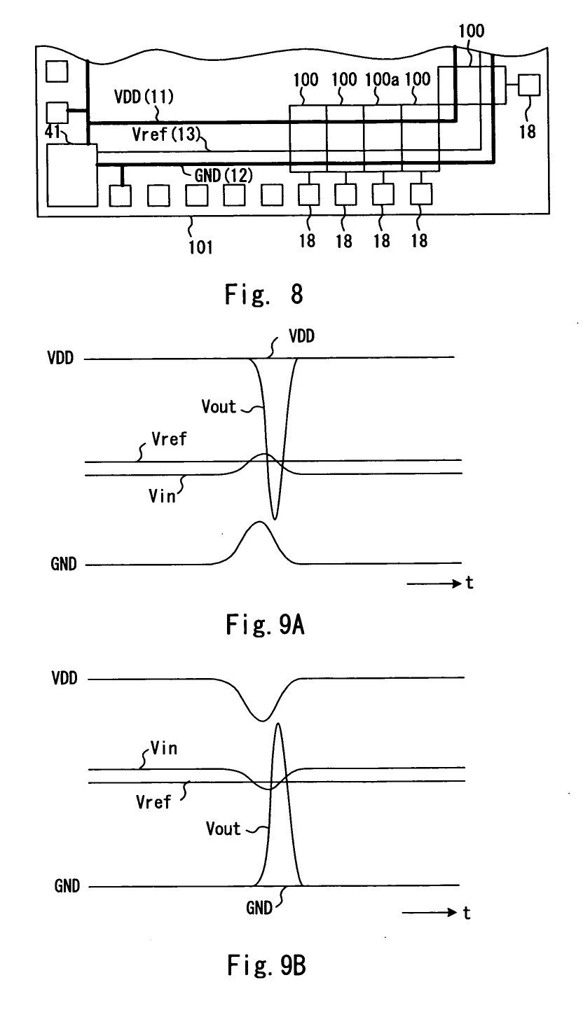

This embodiment is applicable to an integrated circuit of FIG. 8. If the input circuit 10 of this embodiment replaces the conventional input circuit 100 of FIG. 8, even when the high-frequency noise is superimposed on the power supply line 11 or ground line 12, the integrated circuit free from erroneous operation can be attained. Further, in the input circuit 10, the capacitor elements 22 and 24 can be made up of the upper metal wiring layer alone, and an additional resistor is not required. Thus, an area occupied by the input buffer circuit and the power consumption can be prevented from increasing.

### Second Embodiment of the Invention

Next, an integrated circuit according to a second embodiment of the present invention is described. The integrated circuit according to this embodiment has a low-pass filter for removing the high-frequency noise of the original reference voltage applied from the reference voltage generator circuit is provided.

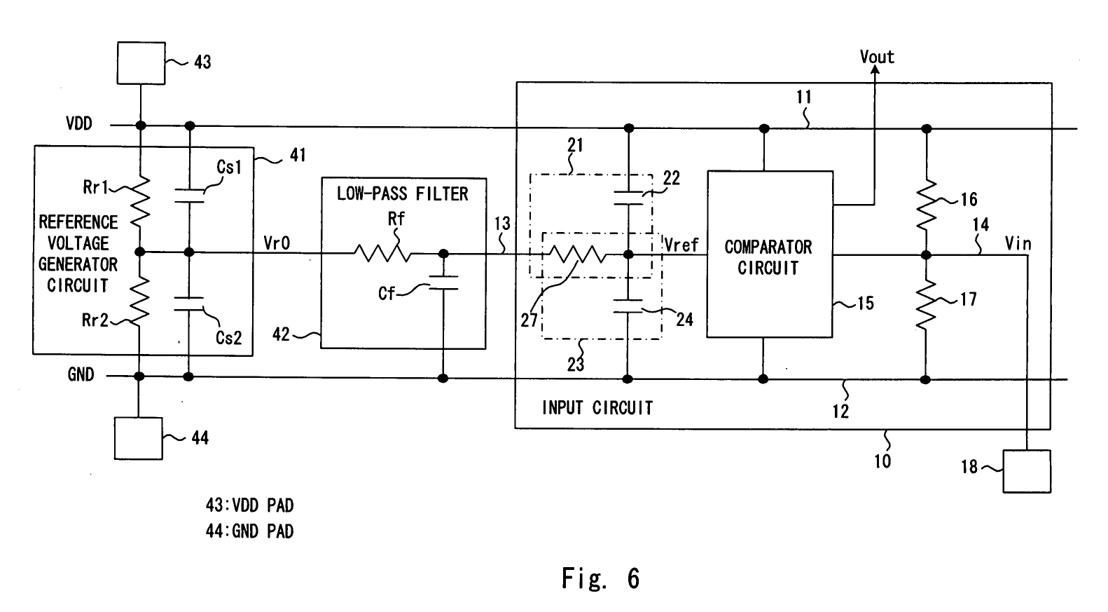

FIG. 6 is a circuit diagram showing an integrated circuit according to this embodiment. In FIG. 6, the same components as those of FIG. 1 are denoted by like reference numerals, and their description is omitted here.

In this embodiment, a low-pass filter 41 is inserted between the reference voltage generator circuit 41 and the input circuit 10. The low-pass filter 41 mainly allows signals having frequency components much lower than the high-frequency noise components assumed to be superimposed on the power supply line 11 or ground line 12, for example, frequency components of 1 MHz or lower. For example, even if the high-frequency noise is superimposed on the reference voltage Vr0 on the way from the original reference voltage generator circuit 41 to the low-pass filter 41, the reference voltage Vref from which noise components are removed through the low-pass filter 41 can be applied to the input circuit 10 by way of the reference voltage supply line 13. The fluctuation in reference voltage is suppressed through the low-pass filter 41 before applied to the input circuit 10, so the influence of noise due to other factors can be eliminated, and the reference voltage Vref applied to the input circuit 10 can be changed in accordance with the change in power supply voltage VDD and ground voltage GND while keeping the difference from the input signal voltage Vin.

The reference voltage generator circuit 41 is applied with the power supply voltage VDD and the ground voltage GND to generate and output the original reference voltage Vr0. As shown in FIG. 6, the reference voltage generator circuit 41 divides the voltage between the power supply voltage VDD and the ground voltage GND by means of resistor elements Rr1 and Rr2 to generate the original reference voltage Vr0. Denoted by reference symbols Cs1 and Cs2 are capacitor elements for stabilizing the original reference voltage Vr0 against the externally generated noise. The reference voltage generator circuit 41 is provided near the power supply voltage VDD supplying pad 43 and the ground voltage GND supplying pad 44, thereby suppressing the fluctuation in original reference voltage Vr0. However, this circuit configuration is illustrated by way of example, and may be replaced by other known reference voltage generator circuits such as a band gap reference type.

As shown in FIG. 6, the low-pass filter 41 may consists, for example, a resistor element Rf and a capacitor element Cf. The change in original reference voltage Vr0 due to the long period variation (low-frequency noise) of the power supply voltage VDD or ground voltage GND is reflected on the input circuit 10 as the change in reference voltage Vref. In contrast, in the case of using the long wire for supplying the original reference voltage Vr0, the high-frequency noise due to the signal change of the surrounding signal lines is superimposed on the original reference voltage Vr0, but the low-pass filter 41 removes the high-frequency noise and applies the resultant reference voltage Vref to the input circuit 10.

The capacitor element Cf in the low-pass filter 41 is separated from the capacitor elements 22 and 24 in the input circuit 10 by the resistor element 27. Similar to the first embodiment, the reference voltage supply line 13 of the resistor element 27 may be formed of metal having a relatively high specific resistance such as tungsten (W) or polysilicon with the metal silicide surface.

The resistor element Rf of the low-pass filter 41 may be formed of metal having a relatively high specific resistance such as tungsten (W) or polysilicon with the metal silicide surface, but if the reference voltage generator circuit 41 is far from the low-pass filter 41, the metal wire of a low specific resistance such as an aluminum (Al) alloy or copper (Cu) can be used for the resistor element as it is.

As mentioned above, in the integrated circuit of this embodiment, the low-pass filter is provided between the reference voltage generator circuit and the input circuit, so the high-frequency noise superimposed on the original reference voltage can be removed, and the noise-free reference voltage can be applied to the input circuit. Therefore, in the input circuit, the reference voltage can follow the input signal voltage without being influenced by noise generated in the reference voltage generator circuit etc., thereby preventing the erroneous operation without fail.

In the above example, the resistor elements 16 and 17 are connected between the input line 14, and both the power supply line 11 and the ground line 12, but the resistor element may be connected only between the power supply line and either the power supply line 11 or the ground line 12. In this case, the high-pass filter may be provided on one of the power supply line 11 side and the ground line 12 side where the resistor element is formed, not on both of them.

Further, not only the resistor element but a capacitor element may be provided between the input line 14 and either the power supply line 11 or the ground line 12.

It is apparent that the present invention is not limited to the above embodiment and it may be modified and changed without departing from the scope and spirit of the invention.

What is claimed is:

1. An input circuit, comprising:
a comparator circuit comparing a reference voltage with an input voltage;
a resistor element provided between a power supply line supplying a power supply voltage of the comparator circuit and an input line applied with the input voltage; and
a transmitting circuit transmitting a voltage change of the power supply line to a reference voltage supply line supplying the reference voltage.

2. The input circuit according to claim 1, wherein the transmitting circuit is a high-pass filter.

3. The input circuit according to claim 1, wherein the transmitting circuit includes a capacitor element.

4. The input circuit according to claim 2, wherein the transmitting circuit includes a capacitor element.

5. An input circuit, comprising:
a comparator circuit comparing a reference voltage supplied from a reference voltage supply line and an input voltage supplied from an input line;
a first resistor element provided between a first power supply line supplying a first voltage and the input line;
a second resistor element provided between a second power supply line supplying a second voltage and the input line;
a first high-pass filter provided between the reference voltage supply line and the first power supply line; and
a second high-pass filter provided between the reference voltage supply line and the second power supply line.

6. The input circuit according to claim 5, wherein the first high-pass filter includes a first capacitor element, and the second high-pass filter includes a second capacitor element.

7. The input circuit according to claim 5, wherein the first high-pass filter includes a first capacitor element and a third resistor element which are connected in series,
the second high-pass filter includes a second capacitor element and a fourth resistor element which are connected in series, and
the reference voltage is applied to the comparator circuit through a node between the first capacitor element and the third resistor element and a node between the second capacitor element and the fourth resistor element.

8. The input circuit according to claim 7, wherein the third resistor element and the fourth resistor element are metal lines.

9. The input circuit according to claim 5, wherein the first high-pass filter consists of a first capacitor element and a third resistor element,
the second high-pass filter consists of a second capacitor element and the third resistor element, and
the reference voltage is supplied to the comparator circuit through a node connected in common with the first capacitor element, the second capacitor element and the third resistor element.

10. The input circuit according to claim 9, wherein the third resistor element is a metal line.

11. The input circuit according to claim 6, wherein a ratio between a capacitance value of the first capacitor element and a capacitance value of the second capacitor element is substantially the same as a ratio between a resistance value of the first resistor element and a resistance value of the second resistor element.

12. The input circuit according to claim 7, wherein a ratio between a capacitance value of the first capacitor element and a capacitance value of the second capacitor element is substantially the same as a ratio between a resistance value of the first resistor element and a resistance value of the second resistor element.

13. The input circuit according to claim 9, wherein a ratio between a capacitance value of the first capacitor element and a capacitance value of the second capacitor element is substantially the same as a ratio between a resistance value of the first resistor element and a resistance value of the second resistor element.

14. A semiconductor device comprising an input circuit, the input circuit comprising:
a comparator circuit comparing a reference voltage with an input voltage;
a resistor element provided between a power supply line supplying a power supply voltage of the comparator circuit and an input line applied with the input voltage; and
a transmitting circuit transmitting a voltage change of the power supply line to a reference voltage supply line supplying the reference voltage.

15. The semiconductor device according to claim 14, wherein the transmitting circuit is a high-pass filter.

16. The semiconductor device according to claim 14, wherein the transmitting circuit includes a capacitor element.

17. The semiconductor device according to claim 14, further comprising:
a reference voltage generator circuit generating the reference voltage; and
a low-pass filter removing high-frequency components of the generated reference voltage to supply the reference voltage to the comparator circuit.
